(19) United States
(12) Patent Application Publication
(10) Pub. No.: US 2005/0212515 A1
(43) Pub. Date: Sep. 29, 2005

(54) Biomagnetic measurement apparatus and method for setting horizontal position for biomagnetic measurement

(76) Inventors: Atsushi Watanabe, Hitachinaka (JP); Masahiro Murakami, Hitachinaka (JP); Kenji Teshigawara, Hitachinaka (JP); Yoshio Matsuoka, Hitachinaka (JP)

Correspondence Address: DICKSTEIN SHAPIRO MORIN & OSHINSKY LLP, 2101 L Street, NW, Washington, DC, 20037, US

(21) Appl. No.: 11/055,082

(22) Filed: Feb. 11, 2005

(30) Foreign Application Priority Data
Mar. 26, 2004 (JP) 2004-090803

(51) Int. Cl. G01R 33/02

(52) U.S. Cl. 324/248

(57) ABSTRACT

A biomagnetic measurement apparatus that readily enables the positional adjustment of a test object in biomagnetic measurement and a biomagnetic measurement method are provided. In biomagnetic measurement, in the case where the test object is a heart, for example, a permanent magnet is disposed on the body surface of the xiphoid process of a subject and the pectoral region is disposed under the bottom face of the cryogenic container. A processing unit stores the calibration curve of the permanent magnet and performs a process for estimating the positional relationship between the subject and the bottom face of the cryogenic container in accordance with the measurement result of the magnetic field strength of the permanent magnet. Also, the processing unit performs a process for estimating the distance between the body surface of the test object and the bottom face of the cryogenic container.

### CLAIM OF PRIORITY

The present application claims priority from Japanese application JP 2004-90803 filed on Mar. 26, 2004, the content of which is hereby incorporated by reference into this application.

### BACKGROUND OF THE INVENTION

1. Field of the Invention

The present invention relates to a biomagnetic measurement apparatus that measures a faint magnetic field (magnetism) emitted from the brain or the heart, for example, of a living body by using a SQUID (Superconducting Quantum Interference Device) magnetometer, which is a superconducting device. Especially, the present invention relates to a biomagnetic measurement apparatus that is capable of readily adjusting the position of a subject and the position of the magnetometer, and correcting data.

2. Background Art

In a biomagnetic measurement apparatus, it is difficult to accurately grasp the positional relationship between a subject and magnetic field sensors, since a SQUID magnetometer is disposed inside an opaque heat-insulating container, such as a dewar. As means for grasping the positional relationship, in a technology regarding magnetoencephalography disclosed in Patent Document 1, for example, a plurality of SQUID magnetometers are disposed on the bottom portion of the dewar whose outer shape is formed in accordance with the curvature of the head, and magnetic fields generated by energizing magnetic field generating coils disposed in a plurality of positions of the cephalic portion are measured using the SQUID magnetometers, thereby simulating the relationship between the magnetic fields emitted by the magnetic field generating coils and the outputs of the SQUID magnetometers. The position coordinates of the cephalic portion where a particular magnetic field generating coil is disposed is specified by estimating the position of the magnetic field generating coil where the difference between a theoretical value and a measurement value of output voltage provided by the SQUID magnetometers is minimized.

In a technology regarding a magnetocardiograph disclosed in Patent Document 2, a first and a second markers are disposed on the body surface of the xiphoid process and the suprasternal notch of a test object, respectively. An abdomen is disposed under the bottom face of a cryogenic container such that a line connecting the first and the second markers stretches along one direction inside the cryogenic container where magnetometers are arranged. A processing unit is performing a process of making an image that shows functional information on cardiac activity from signals in the magnetic field waveform, a process of making a functional image that has the same size of pixels as a form image by disposing the first marker on the body surface of the xiphoid process and making the pixel size of the image that shows functional information correspond to the pixel size of the form image including a heart photographed via an imaging apparatus, a process of matching the position of the first marker in the functional image, and a process of making a synthesized image of the functional image and the form image.

In the biomagnetic measurement apparatus, it is necessary to correct the strength of a magnetic field in the depth direction of a subject. Patent Document 3 discloses a method in which the number N of magnetic field generating coils C₁ to C_{N}, for example, whose disposition location is known, are disposed in the vicinity of the inside bottom portion of a heat-insulating container, for example, such as a dewar. Each parameter of the vector position of a SQUID magnetometer, the direction vector of a detected magnetic field, and the scholar value of a magnetic field sensitivity is estimated from the difference between a theoretical value of the output voltage of the SQUID magnetometer calculated from a theoretical value of a magnetic field generated by a given magnetic field generating coil C_{J} in the SQUID magnetometer position in the case where known current is successively applied and a measurement value of output voltage.

Patent Document 1: JP Patent Publication (Kokai) No. 4-303416 A (1992)

Patent Document 2: JP Patent Publication (Kokai) No. 2001-170018 A

Patent Document 3: JP Patent Publication (Kokai) No. 7-280904 A (1995)

### SUMMARY OF THE INVENTION

In a conventional biomagnetic measurement apparatus, it is necessary to separately conduct the grasp of positional relationship between a subject and a magnetic field sensor and the calibration of the strength of a magnetic field in a depth direction, so that measurement requires a lot of time.

It is an object of the present invention to provide a biomagnetic measurement apparatus and a biomagnetic measurement method that is capable of realizing both the adjustment of a subject position and a magnetic sensor position and the calibration of a magnetometer in the depth direction in a short time and in a simple manner.

The configuration of the present invention is as follows.

The biomagnetic measurement apparatus comprises a SQUID magnetometer for measuring a magnetic field generated from a subject, a marker for attaching to the subject, including a permanent magnet of known magnetic field strength, memory means for storing the relationship between the magnetic field strength of the marker and the distance between the marker and the SQUID magnetometer, and computing means for calculating the position of the subject in the height direction on the basis of the magnetic field strength of the marker measured via the SQUID magnetometer, and the relationship between the magnetic field strength of the marker and the distance between the marker and the SQUID magnetometer stored in the memory means.

Preferably, an adhesive layer is disposed on the attachment surface of the marker so as to directly attach to the subject. However, the marker may be attached via adhesive tape, for example, instead of attaching per se. The marker may be of any size as long as it satisfies the needs for providing sufficient magnetic field strength and is capable of readily attaching to the subject. A disk shape marker whose diameter is about 2 to 3 cm is easy to use, for example, since if it is too small it can be readily be lost.

Magnetic field sensors may be arranged in the two-dimensional direction or in the three-dimensional direction in order to examine the magnetic field distribution of the subject in the two-dimensional direction or in the three-dimensional direction. If the magnetic field sensors are disposed in the two-dimensional direction in order to examine the magnetic field distribution of the subject in the horizontal direction, it can be learned that the marker is disposed under a specific magnetic field sensor that detects the strongest magnetic field emitted from the marker. In this manner, computing means for calculating the positions of the marker (i.e., marker-attached subject) and the magnetic field sensor in the horizontal direction may be provided.

Also, calculated marker (subject) in the horizontal direction may be displayed or the difference of the current position of the marker may be displayed with respect to a predetermined target position.

According to the present invention, in the positional adjustment of a test object in biomagnetic measurement, positional information on the test object can be obtained from a permanent magnet of known magnetic field strength, so that the configuration of an apparatus can be simple, and an operation required for the positional adjustment can be concise thereby simplifying the apparatus.

A typical configuration of the biomagnetic measurement apparatus according to the present invention is described. The biomagnetic measurement apparatus according to the present invention comprises a bed for mounting a test object, a holding stand for holding the bed, a plurality of SQUID magnetometers for detecting a magnetic field generated from the heart of the test object, a cryogenic container for cooling the plurality of SQUID magnetometers, a gantry for holding the cryogenic container at a known distance with respect to a floor surface, the gantry being fixed on the floor surface. The bottom face of the cryogenic container and the top face of the bed are disposed in an almost parallel manner with respect to the floor surface.

The plurality of SQUID magnetometers are disposed in the x-axis direction and the y-axis direction in the vicinity of the inside bottom face of the cryogenic container, individually, and detect a component of a magnetic field in the z-axis direction, for example, which is generated from the heart of the test object. The magnetometers detect, as the plurality of SQUID magnetometers, a component of the magnetic field in the z-axis direction, which is generated from the heart of the test object. The magnetometers may be used as the plurality of SQUID magnetometers for detecting a component of the magnetic field in the x-axis direction and in the y-axis direction which is generated from the heart of the test object.

A permanent magnet of known magnetic field strength is used as means for adjusting the positional relationship between the bottom face of the cryogenic container and the test object. The permanent magnet is attached to the body surface of the xiphoid process of the test object mounted on the bed.

Means for moving the position of the bed with respect to the bottom face of the cryogenic container employs x-axis direction movement means for moving the holding stand in the x-axis direction on the floor surface, y-axis direction movement means for moving the bed in the y-axis direction on the holding stand, and z-axis direction movement means for moving the bed in the z-axis direction on the holding stand.

As the position of the bed moves with respect to the bottom face of the cryogenic container, the positional relationship between the bed and the bottom face of the cryogenic container is measured automatically via position measurement means and a measurement result is transmitted to an operator via information transmission means, such as an indicator, voice guidance, or the like. The distance between the bed and the floor surface is automatically measured via distance measurement means and a measurement result is transmitted to an operator via information transmission means, such as an indicator, voice guidance, or the like.

In this configuration, the bed is moved in the x-axis and y-axis directions on the basis of the measurement result of the bed and the bottom face of the cryogenic container via the position measurement means. The positional relationship between the bed and the bottom face of the cryogenic container can be measured and the positional relationship between the test object mounted on the bed and the bottom face of the cryogenic container can be adjusted using a simple configuration. Also, the bed is moved in the z-axis direction on the basis of the measurement result of the bed and the floor surface via the distance measurement means. The height position of the bed can be measured and the positional relationship between the test object mounted on the bed and the bottom face of the cryogenic container can be adjusted using the simple configuration.

In another typical configuration of the biomagnetic measurement apparatus according to the present invention, the plurality of SQUID magnetometers that detect a magnetic field component of a magnetic field in the normal direction, which is generated from the heart of the test object, are disposed on the inside bottom portion of the cryogenic container two-dimensionally and cooled at low temperature. The SQUID magnetometers are driven via a driving circuit and signals in the magnetic field waveform regarding the magnetic field component in the normal direction, which is detected via SQUID magnetometers, are collected via a processing unit, such as a computer, that performs a computing process and control of each portion of the apparatus. Prior to the measurement, the permanent magnet, which is a marker of known magnetic field strength, is disposed on the body surface of the xiphoid process of the test object.

A coordinate system (x, y, z) is set in the biomagnetic measurement apparatus, and the positional relationship between the body surface of the test object on the bed and the bottom portion surface of the cryogenic container is adjusted using the permanent magnet of known magnetic field strength. The xy surface of the coordinate system (x, y, z) is set on a measurement surface of the SQUID magnetometers. The bottom face of the cryogenic container is parallel to the xy surface, the measurement surface, and the top face of the bed, and the distance between the top face of the bed and the bottom face of the cryogenic container is known.

When the test object is mounted on the bed at the lowest height thereof, the permanent magnet is attached to the body surface of the xiphoid process of the test object, the bed is moved such that the permanent magnet is disposed under the bottom face of the cryogenic container, and the magnetic strength of the permanent magnet is measured, for example. On the basis of a measurement result, the bed is moved in the x-axis direction and the y-axis direction such that a predetermined SQUID magnetometer among the plurality of SQUID magnetometers corresponds to a portion that indicates the maximum magnetic field strength, thereby adjusting the position of the test object. Then, the bed is moved in the z-axis direction until the body surface of the test object reaches the bottom face of the cryogenic container and the magnetic field strength is measured. On the basis of a measurement result, the distance between the SQUID magnetometer and the body surface of the test object can be obtained via distance estimation means. Preferably, a xiphoid process position is selected as the body surface position of the test object, since it can be readily determined by palpation with a good repeatability.

The processing unit performs, in an operation regarding the positional adjustment of the test object, (1) a process for specifying a portion (SQUID magnetometer number, for example) that indicates the maximum magnetic field strength among the SQUID magnetometers by measuring the magnetic field strength of the permanent magnet, (2) a process for calculating the positional relationship between the aforementioned portion that indicates the maximum magnetic field strength and a predetermined SQUID magnetometer, (3) a process for confirming, after the position of the test object is adjusted, that the aforementioned portion that indicates the maximum magnetic field strength corresponds to the predetermined portion, and (4) a process for estimating, after the bed is moved in the z-axis direction until the body surface of the test object reaches the bottom face of the cryogenic container, the distance between the SQUID magnetometer and the body surface of the test object via the distance estimation means.

Further, the processing unit performs process (4) by conducting the following distance estimation means: (a) a process for estimating the distance between the SQUID magnetometer and the body surface of the test object from the measured magnetic field strength of the permanent magnet using the stored calibration curve of the magnetic field strength of the permanent magnet (the relationship between the magnetic field strength of the permanent magnet and the distance between the SQUID magnetometer and the permanent magnet), (b) a process for correcting the sensitivity of the SQUID magnetometer in accordance with the measured magnetic field strength of the permanent magnet, and (c) a process for measuring, after the sensitivity of the SQUID magnetometer is corrected, the magnetic field strength of the permanent magnet again and confirming that the magnetic field strength corresponds to the calibration curve.

### BRIEF DESCRIPTION OF THE DRAWINGS

FIG. 1 shows the entire configuration of a biomagnetic measurement apparatus in a first embodiment of the present invention.

FIG. 2 schematically illustrates of order by which a test object mounted on a bed is disposed under a cryogenic container in the first embodiment of the present invention.

FIG. 3 shows a display example of an image that indicates the movement distance of the bed in the x-axis direction and the y-axis direction in the positional adjustment of the test object as a first example of a display image of information obtained via the biomagnetic measurement apparatus in the first embodiment of the present invention.

FIG. 4 shows an illustration of the movement order of the bed in the x-axis direction and the y-axis direction in the positional adjustment of the test object as an example of order by which the test object mounted on the bed is disposed under the cryogenic container in the first embodiment of the present invention.

FIG. 5 shows a display example of an image that indicates the movement of the bed in the z-axis direction in the positional adjustment of the test object as the first example of the display image of information obtained via the biomagnetic measurement apparatus in the first embodiment of the present invention.

FIG. 6 shows a display example of an image that indicates the distance between the test object and the bottom face of the cryogenic container in the positional adjustment of the test object as an example of the display image of information obtained via the biomagnetic measurement apparatus in the first embodiment of the present invention.

FIG. 7 shows a display example of an image that indicates the movement distance of the bed in the x-axis direction and the y-axis direction in the positional adjustment of the test object as a second example of the display image of information obtained via the biomagnetic measurement apparatus in the first embodiment of the present invention.

FIG. 8 shows a display example of an image that indicates the movement of the bed in the z-axis direction in the positional adjustment of the test object as the second example of the display image of information obtained via the biomagnetic measurement apparatus in the first embodiment of the present invention.

### DESCRIPTION OF THE PREFERRED EMBODIMENTS

The contents of the present invention are described with reference to embodiments.

### Embodiment 1

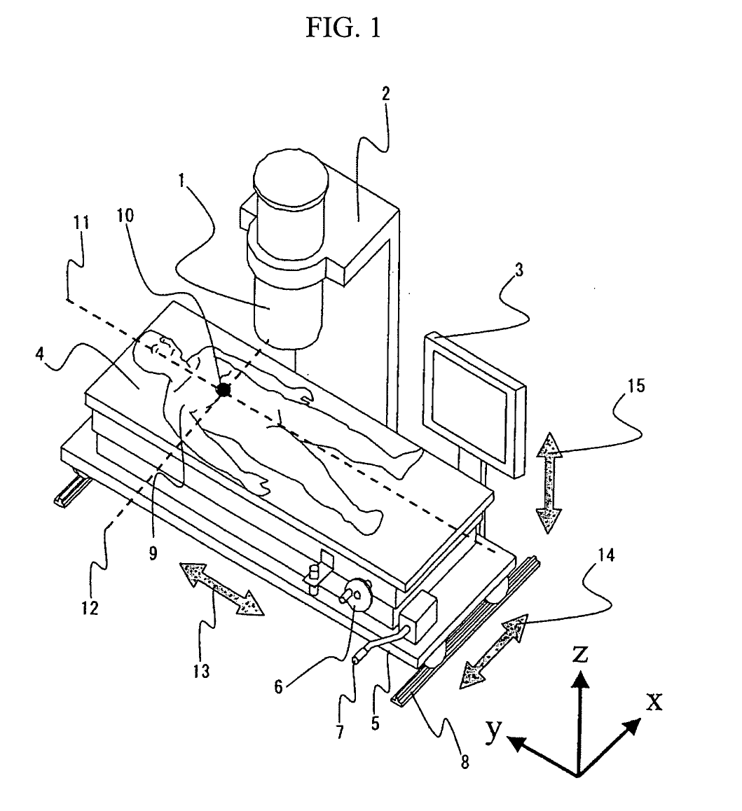

As shown in FIG. 1, the biomagnetic measurement apparatus according to the present invention comprises a cryogenic container 1 for cooling SQUID magnetometers, a gantry 2 for fixing the position of the cryogenic container 1, a monitor 3 for displaying information on the positional adjustment of an object, an inspection bed 4 and a holding stand 5 for holding the bed 4.

The gantry 2 for holding the cryogenic container 1 is fixed on a floor surface. The distance between the bottom face of the cryogenic container 1 and the floor surface is represented by a known value set in advance, and the bottom face of the cryogenic container 1 is in a position fixed with respect to the floor surface. The bottom face of the cryogenic container 1 and the top face of the bed are disposed in an almost parallel manner with respect to the floor surface.

The gantry 2 for holding the cryogenic container 1 is fixed on the floor surface and the bottom face of the cryogenic container 1 may be tilted arbitrarily with respect to the floor surface instead of fixing the bottom face of the cryogenic container 1 with respect to the floor surface. In this case, a test object 9 is disposed in an almost parallel manner with respect to the bottom face of the cryogenic container 1.

A plurality of SQUID magnetometers employ magnetometers for detecting a magnetic field component in the z-axis direction 15 or magnetometers for detecting a magnetic field component in the x-axis direction 14 and in the y-axis direction 13.

A marker used for adjusting the positional relationship between the bottom face of the cryogenic container 1 and the test object 9 employs a permanent magnet 10 of known magnetic field strength. The permanent magnet 10 is attached to the body surface of the xiphoid process of the test object 9 mounted on the bed 4.

Means for moving the position of the bed 4 with respect to the bottom face of the cryogenic container 1 employs a feed rail 8 for moving the holding stand 5 in the x-axis direction 14 on the floor surface, a right/left feed handle 6 for moving the bed 4 in the y-axis direction 13 on the holding stand 5, and a hydraulic pump handle 7 for moving the bed 4 in the z-axis direction 15 on the holding stand 5.

As the position of the bed 4 moves with respect to the bottom face of the cryogenic container 1, the positional relationship between the test object 9 mounted on the bed 4 and the bottom face of the cryogenic container 1 is automatically measured via position measurement means and a measurement result is displayed on the monitor 3.

Further, as the position of the bed 4 moves with respect to the bottom face of the cryogenic container 1, the distance between the test object 9 mounted on the bed 4 and the bottom face of the cryogenic container 1 is automatically measured via distance measurement means and a measurement result is displayed on the monitor 3.

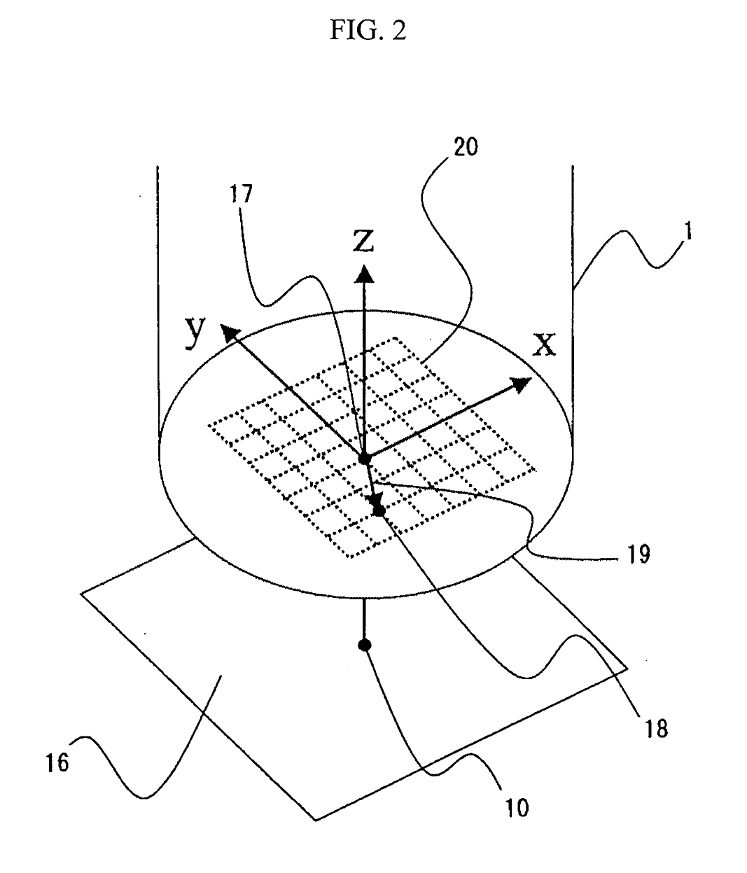

As shown in FIG. 2, on an area in the vicinity of the inside bottom face of the cryogenic container 1, a plurality of SQUID magnetometers 20 are disposed and cooled, individually, in the x-axis direction and in the y-axis direction. A typical method for determining the position of the test object according to the present invention, which is used for the biomagnetic measurement apparatus, employs a coordinate system (x, y, z). The xy surface is parallel to the bottom face of the cryogenic container 1, and the z axis is perpendicular to the bottom face of the cryogenic container 1. The permanent magnet 10 is attached to a body surface 16 of the test object when the test object is mounted on the bed at the lowest height thereof. The bed is moved in the x-axis direction and the y-axis direction such that the permanent magnet 10 is disposed under the bottom face of the cryogenic container 1, and the magnetic strength of the permanent magnet 10 is measured. On the basis of a measurement result, a movement direction 19 of the test object is determined so that a marker 17 of a SQUID magnetometer that indicates the maximum magnetic field strength among the plurality of SQUID magnetometers 20 can correspond to a marker 18 that indicates the target point of positional adjustment. Although the marker that indicates the target point has an initial setting value, it may be changed arbitrarily by an operator.

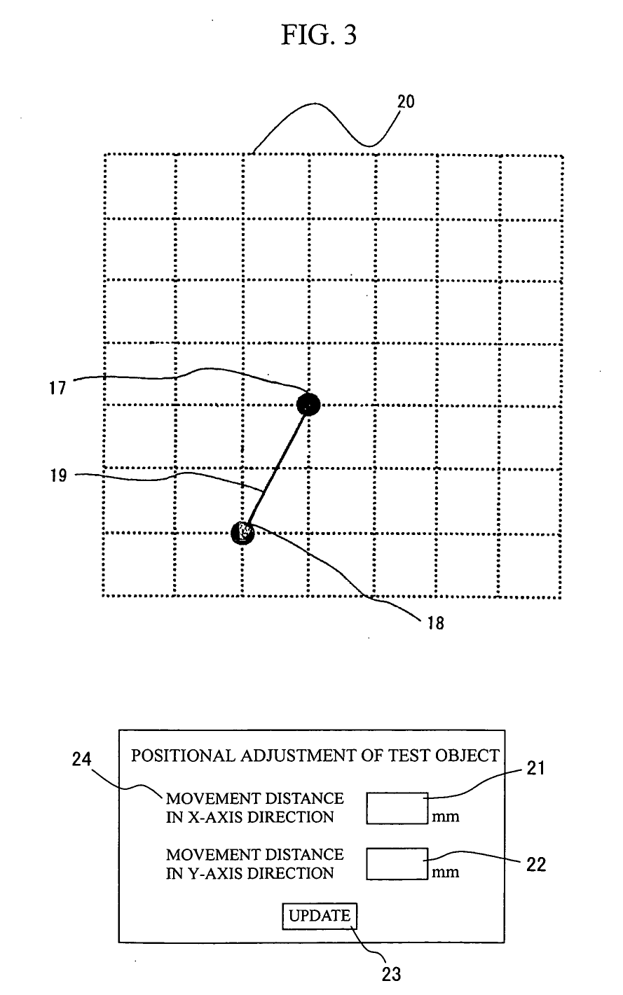

As shown in FIG. 3, the display specification of the positional adjustment of the test object is displayed on the monitor on the basis of the magnetic field measurement result of the permanent magnet, including the SQUID magnetometers 20 and a dialog box 24 that indicates the measurement result obtained with the position measurement means. On the SQUID magnetometers 20, the movement direction 19 of the test object is displayed so that the marker 17 of the SQUID magnetometer that indicates the maximum magnetic field strength among the plurality of SQUID magnetometers 20 can correspond to the marker 18 that indicates the target point of the positional adjustment. On the dialog box 24 that indicates the measurement result obtained with the position measurement means, a movement distance 21 of the test object in the x-axis direction and a movement distance 22 of the test object in the y-axis direction are displayed so that the marker 17 of the SQUID magnetometer that indicates the maximum magnetic field strength among the plurality of SQUID magnetometers 20 can correspond to the marker 18 that indicates the target point of the positional adjustment. Moreover, an icon 23 that indicates data update is displayed in accordance with the change of the positional relationship between the bottom face of the cryogenic container 1 and the test object 9.

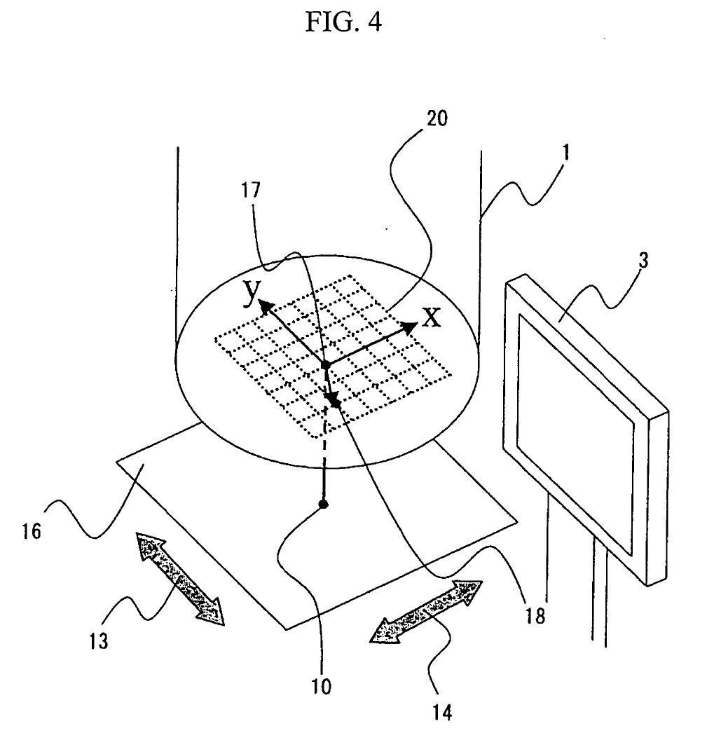

As shown in FIG. 4, the bed is moved in the x-axis direction 14 and in the y-axis direction 13 in accordance with the indication of the monitor 3 so that the marker 17 of the SQUID magnetometer that indicates the maximum magnetic field strength among the plurality of SQUID magnetometers 20 can correspond to the marker 18 that indicates the target point of the positional adjustment. In this case, the indication of the positional adjustment may be supported by a buzzer, or voice transmission means of voice guidance.

Also, in FIG. 4, the bottom face of the cryogenic container 1 may be tilted arbitrarily with respect to the floor surface in accordance with the indication of the monitor 3 so that the marker 17 of the SQUID magnetometer that indicates the maximum magnetic field strength among the plurality of SQUID magnetometers 20 can correspond to the marker 18 that indicates the target point of the positional adjustment. In this case, the test object 9 is disposed in an almost parallel manner with respect to the bottom face of the cryogenic container 1.

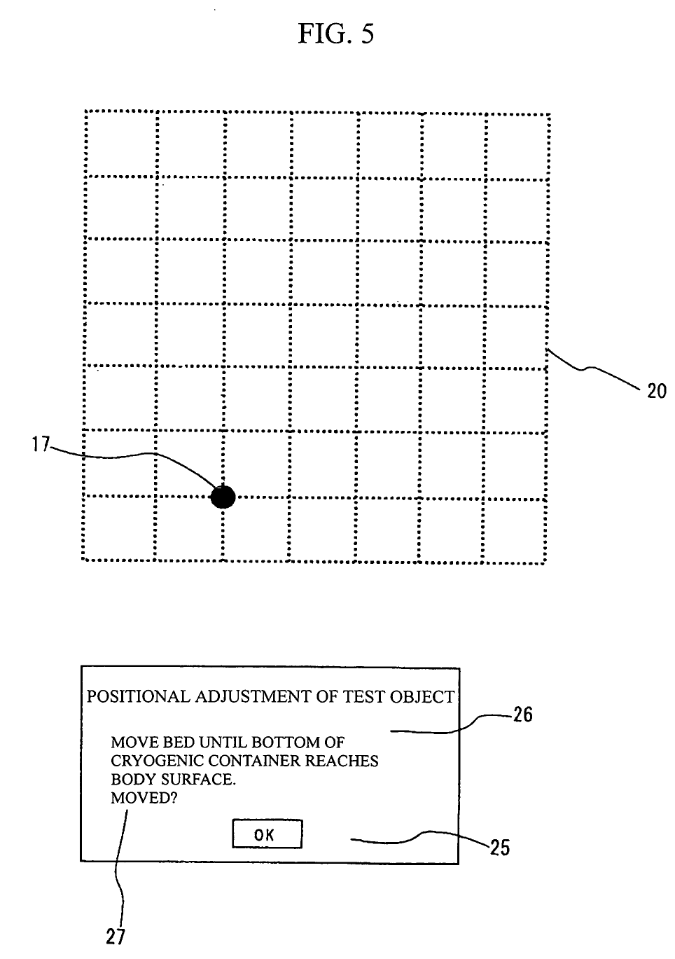

As shown in FIG. 5, the display specification of the positional adjustment of the test object is displayed on the monitor, including the SQUID magnetometers 20 and a dialog box 25 for the confirmation of the end of the positional adjustment in the z-axis direction. On the SQUID magnetometers 20, the marker 17 of the SQUID magnetometer that indicates the maximum magnetic field strength is displayed. Also, on the dialog box 25 for the confirmation of the end of the positional adjustment in the z-axis direction, a display 26 for indicating the positional adjustment and a display 27 for the confirmation of the end of the positional adjustment are displayed.

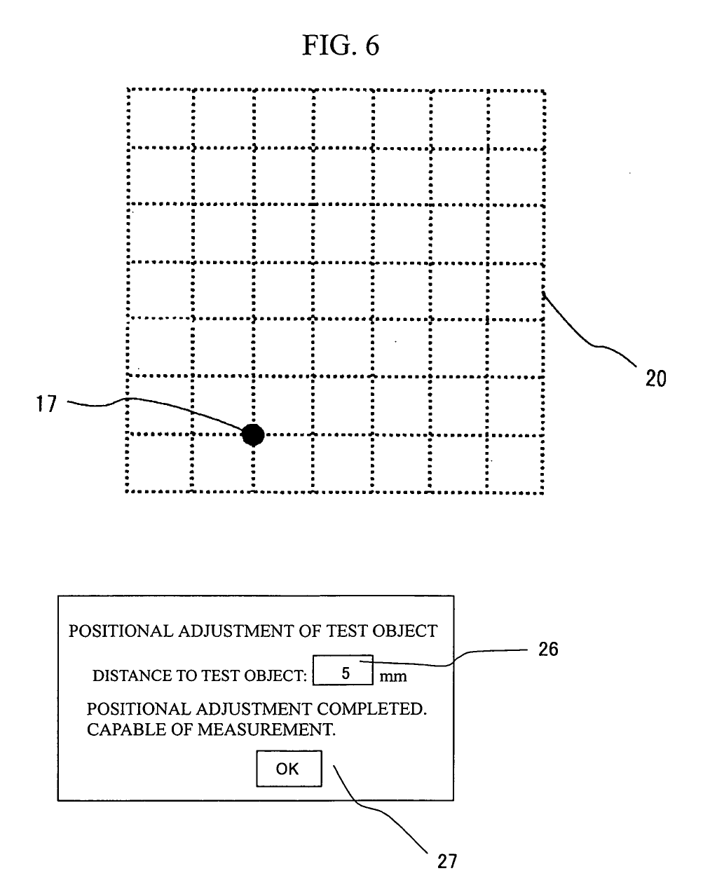

As shown in FIG. 6, the display specification of the positional adjustment of the test object is displayed on the monitor on the basis of the magnetic field measurement result of the permanent magnet, including the SQUID magnetometers 20 and a dialog box 29 that indicates the measurement result obtained with the distance measurement means. On the SQUID magnetometers 20, the marker 17 of the SQUID magnetometer that indicates the maximum magnetic field strength is displayed. Also, on the dialog box 29 that indicates the measurement result obtained with the distance measurement means, the distance between the test object and the bottom face of the cryogenic container is displayed.

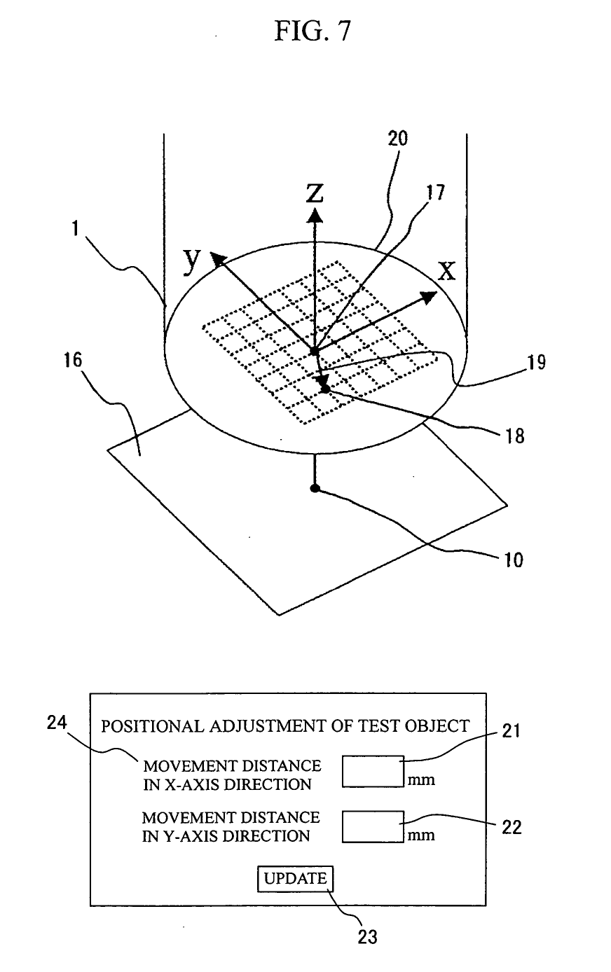

As shown in FIG. 7, the display specification of the positional adjustment of the test object is displayed on the monitor on the basis of the magnetic field measurement result of the permanent magnet, including the cryogenic container 1, the body surface 16 of the test object, the SQUID magnetometers 20 and a dialog box 24 that indicates the measurement result obtained with the position measurement means. On the SQUID magnetometers 20, the movement direction 19 of the test object is displayed so that the marker 17 of the SQUID magnetometer that indicates the maximum magnetic field strength among the plurality of SQUID magnetometers 20 can correspond to the marker 18 that indicates the target point of the positional adjustment. The permanent magnet is displayed on the body surface 16 of the test object. On the dialog box 24 that indicates the measurement result obtained with the position measurement means, the movement distance 21 of the test object in the x-axis direction and the movement distance 22 of the test object in the y-axis direction are displayed so that the marker 17 of the SQUID magnetometer that indicates the maximum magnetic field strength among the plurality of SQUID magnetometers 20 can correspond to the marker 18 that indicates the target point of the positional adjustment. Moreover, the icon 23 for calculating movement distance is displayed in accordance with the movement of the bed.

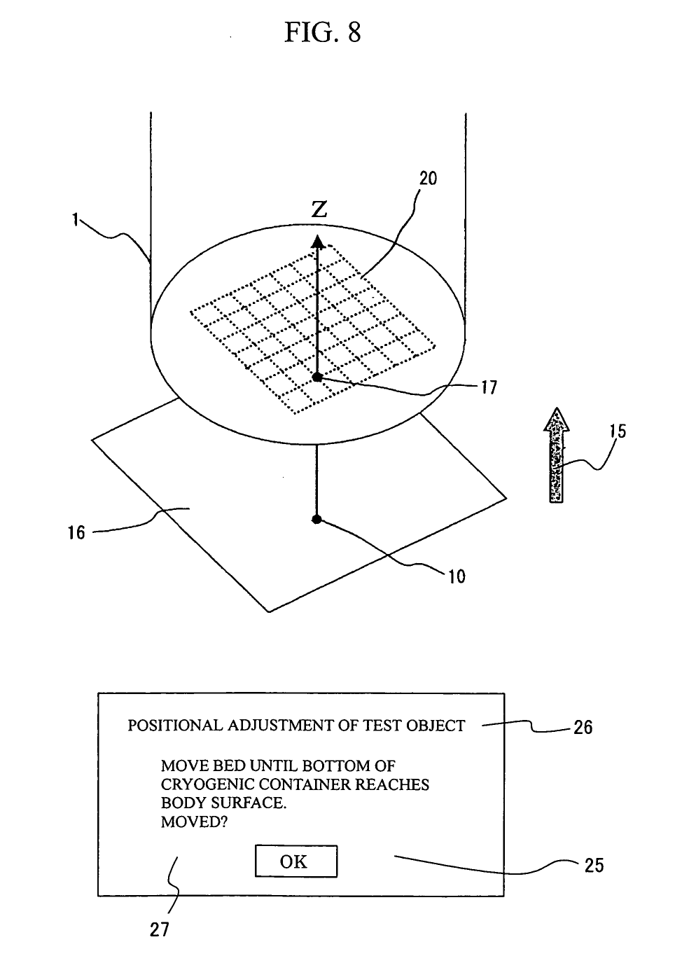

As shown FIG. 8, the display specification of the positional adjustment of the test object is displayed on the monitor on the basis of the magnetic field measurement result of the permanent magnet, including the cryogenic container 1, the body surface 16 of the test object, the SQUID magnetometers 20 and the dialog box 25 that instructs the positional adjustment in the z-axis direction. On the SQUID magnetometers 20, the marker 17 of the SQUID magnetometer that indicates the maximum magnetic field strength among the plurality of SQUID magnetometers 20 is displayed. The permanent magnet is displayed on the body surface 16 of the test object. On the dialog box 25 that instructs the positional adjustment in the z-axis direction, the measurement result obtained with the position measurement means and the instruction of positional adjustment in the z-axis direction are displayed.

### Embodiment 2

The marker including the permanent magnet is attached to the xiphoid process portion of the subject and a form image including the pectoral region is obtained via a three-dimensional X-ray CT apparatus. The marker is shown in an X-ray CT cross-sectional image on a CT image. Then, the subject is measured via the biomagnetic measurement apparatus according to Embodiment 1 regarding the change of the magnetic field strength, and a functional image is obtained (showing an isofield contour map, a current-arrow map, an isofield-integral map, and functional information on cardiac activity in an estimated position of an activated region (current source), for example). Since the position of the heart of the subject is not clear with the functional image obtained by the biomagnetic measurement apparatus, the form image including the pectoral region obtained by the X-ray CT apparatus and the functional image obtained by the biomagnetic measurement apparatus are superposed, thereby obtaining a synthesized image. Processes for obtaining the synthesized image include a process for making the pixel size of the functional image obtained by the biomagnetic measurement apparatus correspond to the pixel size of the cross-sectional image obtained by the three-dimensional X-ray CT apparatus, and a process for making the center position (equivalent to the position of a measurement surface that the z-axis of the coordinate system (x, y, z) of the biomagnetic measurement apparatus goes through) of the reference point in the functional image obtained by the biomagnetic measurement apparatus correspond to the reference point (the center point of the image of a marker including a permanent magnet) photographed in the cross-sectional image.

1. A biomagnetic measurement apparatus, comprising:
a SQUID magnetometer for measuring a magnetic field generated from a subject;
a marker for attaching to the subject, said marker including a permanent magnet of known magnetic field strength;
memory means for storing the relationship between the magnetic field strength of said marker and the distance between said marker and said SQUID magnetometer; and
computing means for calculating the position of the subject in the height direction on the basis of the magnetic field strength of said marker measured via said SQUID magnetometer, and the relationship between the magnetic field strength of said marker and the distance between said marker and said SQUID magnetometer stored in said memory means.

2. The biomagnetic measurement apparatus according to claim 1, further comprising:
a plurality of said SQUID magnetometers; and
computing means for calculating the position of the subject in the horizontal direction on the basis of the measurement result of the magnetic field strength of said marker obtained with said plurality of SQUID magnetometers.

3. The biomagnetic measurement apparatus according to claim 2, comprising:
output means for outputting the calculation result provided by said computing means regarding the position of the subject in the horizontal direction.

4. The biomagnetic measurement apparatus according to claim 3, wherein:
said output means comprises a function for outputting the target position of the subject position in the horizontal direction along with the calculation result of the subject position in the horizontal direction.

5. The biomagnetic measurement apparatus according to claim 4, comprising:
alarm means for notifying an operator when the target position of the subject position in the horizontal direction corresponds to the calculation result of the subject position in the horizontal direction.

6. The biomagnetic measurement apparatus according to claim 1, comprising:
correction means for correcting, after the distance between said marker and said SQUID magnetometer is set to be a predetermined value, the sensitivity of said SQUID magnetometer on the basis of the magnetic field strength of said marker measured via said SQUID magnetometer.

7. A method for setting a horizontal position for biomagnetic measurement, comprising the steps of:
disposing a subject at a measurement position;
attaching a marker including a permanent magnet of known magnetic field strength to a predetermined position of the disposed subject;
measuring a magnetic field strength emitted from said marker using a plurality of SQUID magnetometers;
calculating the position of the subject in the horizontal direction on the basis of the measurement result regarding the magnetic field strength from said marker obtained with said plurality of SQUID magnetometers.

8. The method for setting a horizontal position for biomagnetic measurement according to claim 7, comprising a step of:
displaying the target position of the subject position in the horizontal direction and moving the disposed position of the subject such that the subject position in the horizontal direction corresponds to the displayed target position of the subject position in the horizontal direction.
